(19) United States
(12) Patent Application Publication
(10) Pub. No.: US 2010/0013047 A1
(43) Pub. Date: Jan. 21, 2010

(54) INTEGRATED CIRCUIT AND METHOD OF MANUFACTURING THE SAME

(76) Inventors: Andreas Thies, Berlin (DE); Klaus Muemmler, Dresden (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 12/174,434

(22) Filed: Jul. 16, 2008

(51) Int. Cl. H01L 29/00; H01L 21/20

(52) U.S. Cl. 257/532; 438/386; 257/E29.001; 257/E21.09

(57) ABSTRACT

An integrated circuit on a substrate comprises a buffer capacitor in a buffer region. The buffer capacitor comprises a buffer electrode arranged at least partially in a recess, and a dielectric layer disposed between the buffer electrode and the substrate.

### BACKGROUND

1. Field of the Invention

The present invention generally relates to integrated circuit devices and to methods of manufacturing the same.

2. Description of the Related Art

Integrated circuit devices typically comprise so-called buffer capacitors in order to stabilize a voltage supply. The buffer capacitors may be used to filter voltage peaks in the event of load changes that may occur suddenly or due to a momentary failure of the voltage supply. For this purpose, the buffer capacitors may be provided on an integrated circuit in such a way that the voltage to be buffered drops across the capacitors.

Conventional concepts for buffering the voltage supply of an integrated circuit include the use of plane gate electrodes (GC, gate conductor) which are located in the support area of the integrated circuit, wherein the semiconductor material of the circuit chip forms the counter electrode of the buffer capacitors. With respect to a memory circuit such as DRAM (Dynamic Random Access Memory), buffer capacitors may be applied which are constructed in a similar way to storage capacitors of memory cells. Here, electrodes of the buffer capacitors may be formed in so-called deep trenches (DT), which have a relatively small lateral base area (e.g. 100 nm in diameter) and a relatively large depth (e.g. ˜several μm). Further conventional buffer concepts relate to stacked capacitors, also referred to as TiO modules (Trench in Oxide), and to so called MIM-capacitors (Metal Insulator Metal).

The provision of buffer capacitors on a circuit chip is associated with an additional lateral space demand, thus reducing the lateral space being available for other components of the circuit chip. Moreover, formation of buffer capacitors may include the application of additional process steps, and therefore additional time and effort in the fabrication of integrated circuits.

### BRIEF DESCRIPTION OF THE DRAWINGS

FIGS. 1 to 6 show schematic plan views and sectional views of a substrate for illustrating steps of a method for fabricating buffer capacitors together with word lines of an integrated circuit, according to one embodiment of the invention;

FIGS. 7 to 10 show sectional views of the substrate for illustrating possible structural differences between buffer capacitors and word lines, according to one embodiment of the invention;

FIG. 11 shows a sectional view of the substrate for illustrating a variant of a buffer capacitor region, according to one embodiment of the invention;

FIG. 12 shows a schematic plan view and a sectional view of the substrate for illustrating a further variant of buffer capacitors, according to one embodiment of the invention;

FIG. 13 shows schematic plan views and sectional views of the substrate for illustrating a further variant of buffer capacitors and word lines, according to one embodiment of the invention;

FIG. 14 shows schematic plan views and sectional views of the substrate for illustrating another variant of buffer capacitors and word lines, according to one embodiment of the invention;

FIGS. 15 to 20 show schematic plan views and sectional views of a substrate for illustrating steps of a method for fabricating buffer capacitors together with bit lines of an integrated circuit, according to one embodiment of the invention;

FIGS. 21 to 24 show sectional views of the substrate for illustrating possible structural differences between buffer capacitors and bit lines, according to one embodiment of the invention;

FIG. 25 shows a schematic sectional view of the substrate for illustrating a variant of buffer capacitors, according to one embodiment of the invention;

FIG. 26 shows a schematic sectional view of a substrate for illustrating another variant of buffer capacitors, according to one embodiment of the invention;

FIG. 27 shows a schematic sectional view of a substrate for illustrating yet another variant of buffer capacitors, according to one embodiment of the invention; and

FIG. 28 shows a flow diagram of a method for manufacturing an integrated circuit, according to one embodiment of the invention.

Various features of embodiments will become clear from the following description, taking in conjunction with the accompanying drawings. It is to be noted, however, that the accompanying drawings illustrate selected embodiments and are, therefore, not to be considered limiting of the scope of the invention. The present invention may admit other equally effective embodiments.

### DETAILED DESCRIPTION

The embodiments described in the following relate to an integrated circuit and to a method of manufacturing the same.

One embodiment includes an integrated circuit on a substrate. The integrated circuit comprises a buffer capacitor in a buffer region and a transistor in an array region of the substrate. The buffer capacitor comprises a number of buffer electrodes and a first dielectric layer. The buffer electrodes are at least partially arranged in recesses formed in the substrate. The first dielectric layer is disposed between the buffer electrodes and the substrate in at least a sidewall portion of the recesses. The transistor comprises a gate electrode and a second dielectric layer. The second dielectric layer is disposed between the gate electrode and the substrate.

Another embodiment includes a method of manufacturing an integrated circuit on a substrate. The method comprises forming first recesses in a buffer region and second recesses in an array region of the substrate, the first and second recesses extending from a surface of the substrate. A dielectric layer is formed on the surface of the substrate in the first and second recesses. The method further comprises forming buffer electrodes of a buffer capacitor in the buffer region and gate electrodes of a transistor in the array region, the buffer electrodes at least partially filling the first recesses and the gate electrodes at least partially filling the second recesses such that the dielectric layer is disposed between the substrate and the buffer electrodes and between the substrate and the gate electrodes. The method furthermore comprises providing an electrical connection between the buffer electrodes and a power line of the integrated circuit.

The embodiments described in the following relate to the fabrication of an integrated circuit device comprising buffer capacitors for stabilizing a voltage supply of the integrated circuit. The integrated circuit may for example be a memory circuit or memory chip such as DRAM, PCRAM (Phase Change RAM), CBRAM (Conductive Bridging RAM), MRAM (Magneto Resistive RAM) and Flash Memory. In the fabrication method, the buffer capacitors and further components of the integrated circuit like for example conductor lines (e.g. word lines and bit lines) or gate electrodes of transistors may be simultaneously formed by carrying out the same or substantially common process steps. As a consequence, fabrication of the buffer capacitors may be performed by means of no or only few additional process steps. The method makes it furthermore possible to fabricate the buffer capacitors in a space-saving manner.

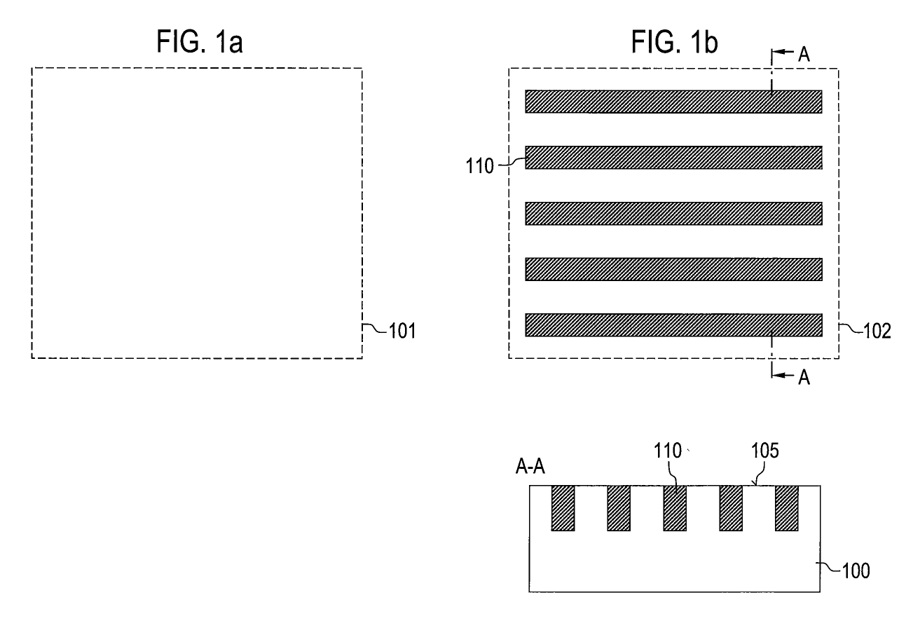

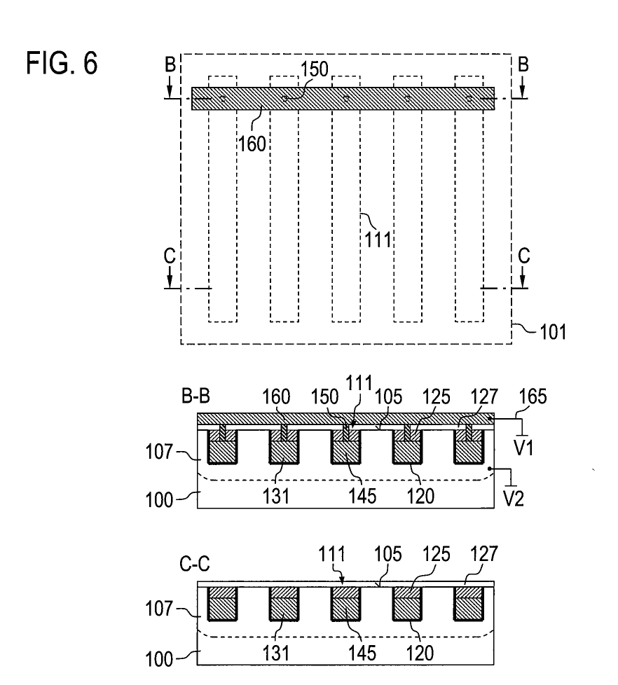

FIGS. 1 to 6 show schematic plan views and sectional views of a substrate 100 for illustrating steps of a method for fabricating buffer capacitors together with word lines of an integrated circuit, according to one embodiment of the invention. The substrate 100, which comprises a semiconductor material such as for example silicon, may e.g. be a semiconductor wafer. The figures include plan views (at the top) and cross-sectional views of substrate regions 101, 102, wherein the cross-sections are denoted by A-A, B-B and C-C. Here, FIGS. 1a to 5a (on the left hand side) and FIG. 6 relate to the fabrication of buffer capacitors of the integrated circuit. The respective substrate region 101 is therefore denoted buffer capacitor region in the following. FIGS. 1b to 5b (on the right hand side) relate to the fabrication of word lines and transistors, e.g. for a memory array of the integrated circuit. The respective substrate region 102 is therefore denoted array region 102 in the following.

As illustrated in FIG. 1b, a number of isolation regions or lines 110 may be fabricated in the array region 102 of the substrate 100, according to one embodiment of the invention. The isolation regions 110 are also referred to as STI (Shallow Trench Isolation). Fabrication of the isolation regions 110 may be carried out by producing respective recesses in the substrate 100 in the form of grooves which extend from a surface 105 of the substrate 100, and filling the recesses with an insulating material, e.g. an oxide material. The isolation regions 110 run substantially parallel to each other.

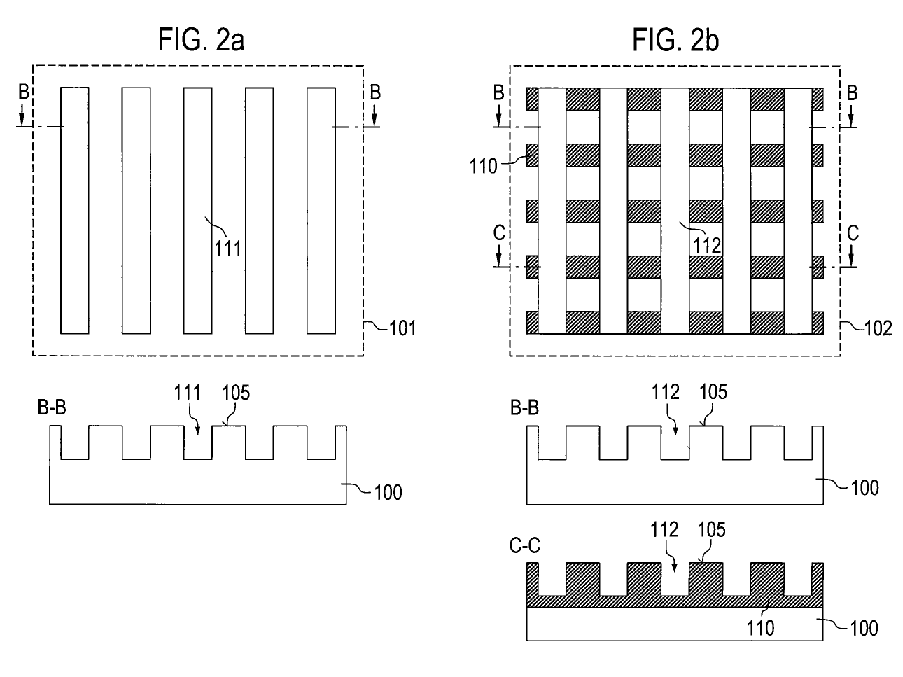

Thereafter, recesses 111 may be formed in the buffer capacitor region 101 (FIG. 2a), and recesses 112 may be formed in the array region 102 of the substrate 100 (FIG. 2b). The recesses 111, 112, which have the form of trenches, may extend from the surface 105 of the substrate 100 and run substantially parallel to each other and to the substrate surface 105. The recesses 112 formed as trenches in the array region 102 furthermore run perpendicular to and penetrate a portion of the isolation regions 110, as indicated in FIG. 2b. At this, the depth of the isolation regions 110 exceeds the depth of the recesses 112.

The recesses 111 and the recesses 112 may comprise the same cross-sectional dimensions and may be fabricated simultaneously. Fabrication of the recesses 111, 112 in the substrate 100 may for example be performed by means of a dry etching process using a respective etching plasma. In the dry etching process, the lateral structure of the recesses 111, 112 may be defined by means of one or several patterned masking layers, which are applied on the substrate surface 105 and which are removed after completing the etching process (not shown). Both the recesses 111 and the recesses 112 may for example have a depth of several 100 nm (e.g. 300 nm) and a length of several μm. The preceding specifications for depth and length are to be considered as examples only and may be replaced by other values.

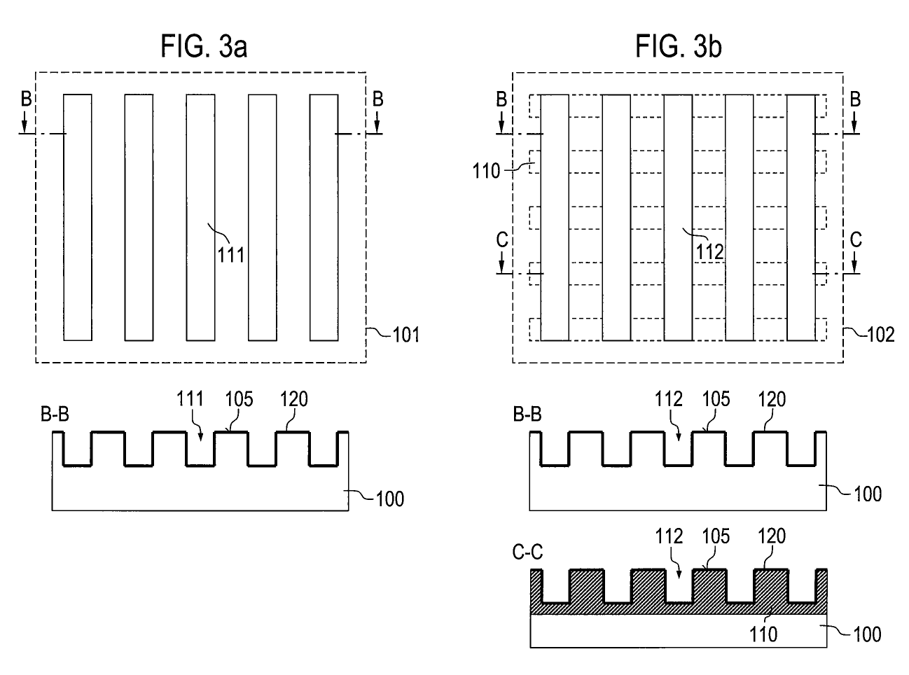

Afterwards, as illustrated in FIGS. 3a and 3b, a dielectric layer 120 may be formed on an edge or sidewall portion of each of the recesses 111 and the recesses 112, according to one embodiment of the invention. Here, the edge portion on which the dielectric layer 120 is formed includes sidewalls and a bottom of the recesses 111, 112. The dielectric layer 120, which may be simultaneously formed in the recesses 111, 112 of the substrate regions 101, 102, may further be formed on the substrate surface 105 outside the recesses 111, 112. The dielectric layer 120 may for example be a silicon oxide layer. Apart from this material, various other materials may be considered for the dielectric layer 120 such as e.g. high-k dielectric materials.

Fabrication of the dielectric layer 120 may for example be carried out by means of a thermal oxidation process, wherein the dielectric layer 120 is thermally grown in a large-area manner on the substrate 100 in the substrate regions 101, 102. Alternatively, it is possible to perform a deposition process like e.g. CVD (Chemical Vapor Deposition) in order to deposit the dielectric layer 120 in a large-area manner on the substrate 100. An example is the so-called TEOS process using tetraethyl orthosilicate (TEOS) as source material. It is furthermore possible to perform a so-called in situ stream generation process (ISSG) in order to fabricate the dielectric layer 120.

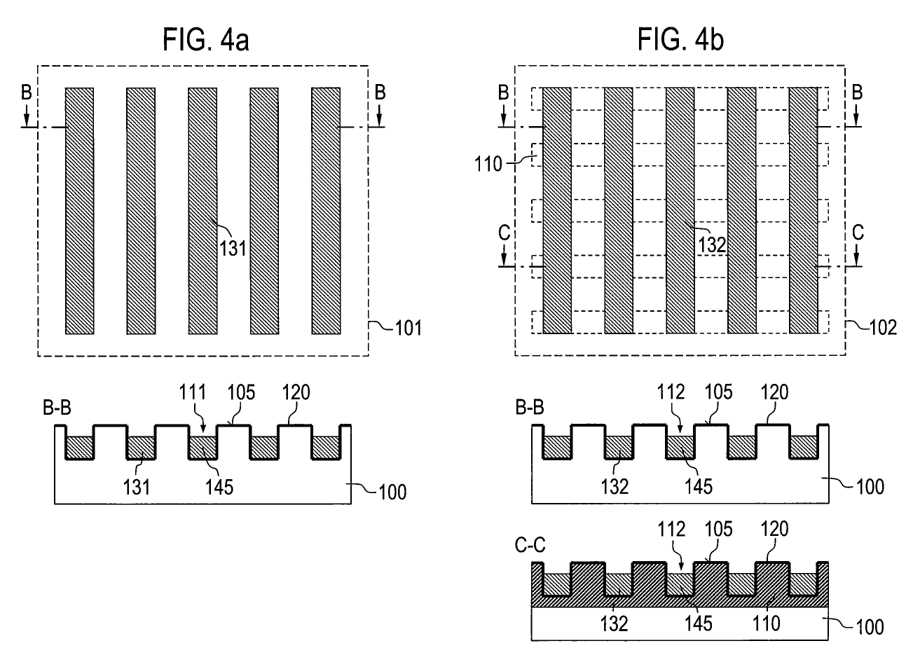

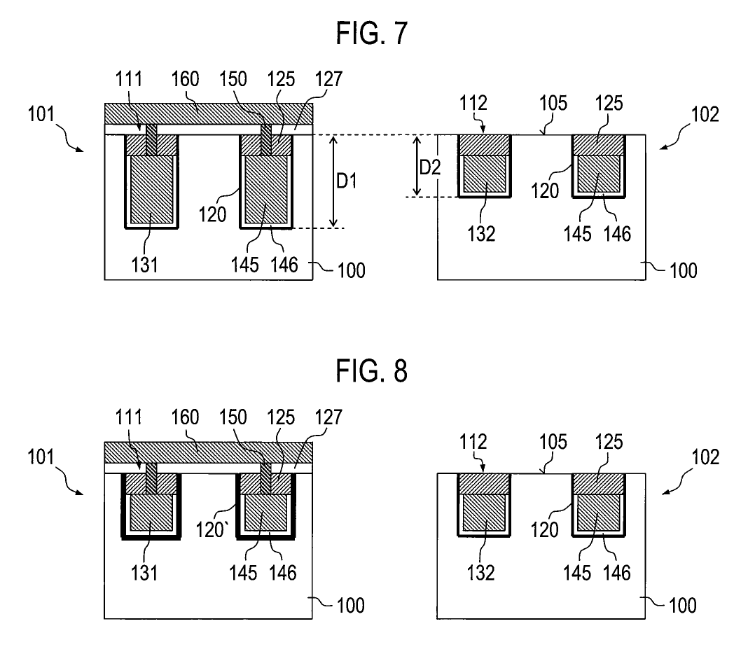

Subsequently, as illustrated in FIGS. 4a and 4b, the recesses 111, 112 may be partially filled with a conductive layer 145, thereby providing conductor portions 131, 132 in a lower recess section of the recesses 111, 112, according to one embodiment of the invention. At this, the conductor portions 131, 132 may be fabricated simultaneously in the substrate regions 101, 102 by applying the same process steps. The conductor portions 131, 132—like the recesses 111, 112—run substantially parallel to each other and to the surface 105 of the substrate 100. The conductor portions 131 in the buffer capacitor region 101 constitute electrodes of buffer capacitors, whereas the conductor portions 132 in the array region 102 are used as word lines and transistor gates, as described further below. Besides the conductive layer 145, the conductor portions 131, 132 may additionally comprise a barrier layer 146 which is provided between the dielectric layer 120 and the conductive layer 145 in the recesses 111, 112 (cf. FIGS. 7 to 10).

The conductive layer 145 of the conductor portions 131, 132 may for example be a metal layer. As an example, the conductive layer 145 may comprise tungsten. Further examples of materials for the conductive layer 145 are metals like copper, aluminum, nickel, gold and silver, or materials like e.g. doped poly silicon and carbon. Materials such as titanium nitride, titanium tungsten, titanium, tantalum, tantalum nitride, ruthenium and nickel phosphorus may also be considered for the conductive layer 145. The conductive layer 145 may comprise the mentioned materials individually or in the form of material mixes or alloys. It is also possible to provide sublayers of different materials in the conductive layer 145. Examples of materials for the optional barrier layer 146 are titanium nitride, titanium tungsten, titanium, tantalum and tantalum nitride. Apart from these materials, various other materials may be considered with respect to the conductive layer 145 and the barrier layer 146.

Fabrication of the conductor portions 131, 132 may for example be carried out by depositing the barrier layer 146 on the substrate 100 in a large-area manner (i.e. on sidewalls and a bottom of the recesses 111, 112 and on the substrate surface 105 outside the recesses 111, 112), followed by depositing the conductive layer 145 on the barrier layer 146 in a large-area manner, thereby filling the recesses 111, 112 with the conductive layer 145, and subsequently partially removing the layers 145, 146 in such a way that the layers 145, 146 remain in the lower recess section of the recesses 111, 112. Deposition processes for depositing the layers 145, 146 may include PVD (Physical Vapor Deposition), CVD or electroplating. Partially removing the layers 145, 146 may for example be carried out by means of a dry etching process, also referred to as recess etching process in this case. An optional polishing process like e.g. CMP (Chemical Mechanical Polishing) may be carried out beforehand, wherein polishing is stopped when reaching the dielectric layer 120 at the substrate surface 105 outside the recesses 111, 112.

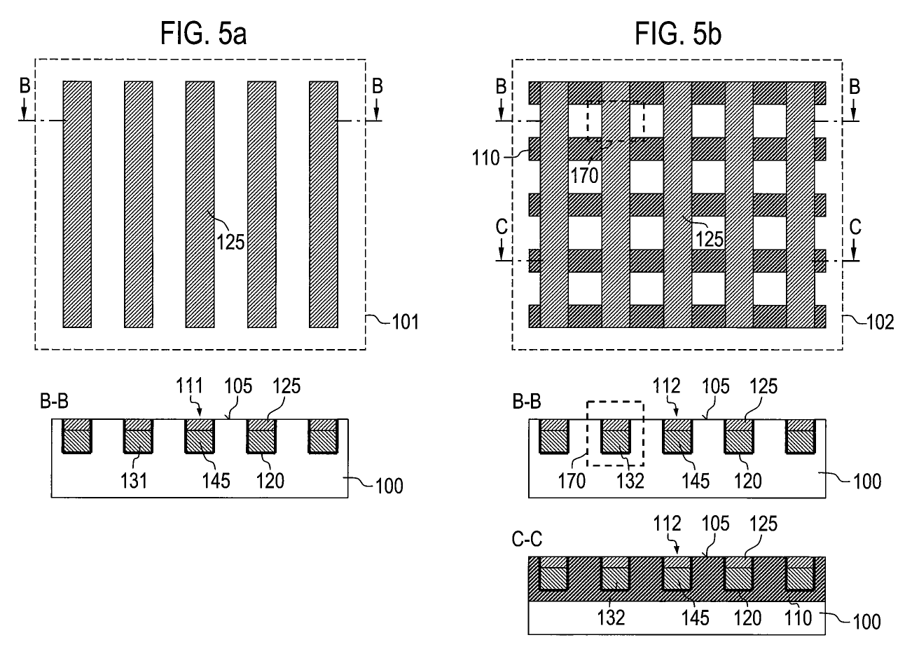

Thereafter, as shown in FIGS. 5a and 5b, a further dielectric layer 125 may be formed in an upper recess section of the recesses 111, 112 covering the conductor portions 131, 132, thereby filling the recesses 111, 112, according to one embodiment of the invention. The further dielectric layer 125, which may for example be an oxide layer, may be simultaneously formed in the substrate regions 101, 102. For this purpose, the dielectric layer 125 may be deposited for example by means of a CVD process on the substrate 100 in a large-area manner (i.e. on the conductor portions 131, 132 in the recesses 111, 112 and on the dielectric layer 120 outside the recesses 111, 112), and by subsequently performing a polishing process like for example CMP, a portion of the dielectric layer 125 outside of the recesses 111, 112 may be removed. In the course of the polishing process, also a portion of the dielectric layer 120 outside the recesses 111, 112 may be removed, thereby exposing the surface 105 of the substrate 100 as illustrated in the sectional views of FIGS. 5a and 5b.

The conductor portions 132 in the array region 102 may serve as word lines of the integrated circuit and—due to the arrangement in the recesses 112—may be referred to as “buried” word lines. In areas between the isolation regions 110, the conductor portions 132 may furthermore serve as gate electrodes of transistors, wherein the dielectric layer 120 represents the gate dielectric. For way of illustration, the plan view of the array region 102 depicted in FIG. 5b indicates a respective active area of a transistor 170. In order to complete the transistors 170 in the array region 102, further processes may be performed. This includes for example ion implant doping in order to form source and drain regions in the substrate 100 close to respective gate electrodes 132 (not shown). Moreover, additional processes to be performed in the array region 102 may for example relate to formation of memory elements and bit lines above the transistors 170 (not shown). In this case, the transistors 170 may serve as selection transistors by means of which memory elements may be connected to bit lines when activating respective word lines 132 during operation of the integrated circuit.

With respect to the buffer capacitor region 101, the conductor portions 131 serve as electrodes of buffer capacitors. Here, the counter electrode of the buffer capacitors may be constituted by the semiconductor material of the substrate 100 which is separated from the conductor portions 131 by the dielectric layer 120 at the sidewalls and the bottom of the recesses 111. In order to provide a parallel circuit of buffer capacitors, the conductor portions 131 are further on electrically connected to each other.

In this regard, FIG. 6 depicts a possible configuration for connection of conductor portions 131 in the buffer capacitor region 101, according to one embodiment of the invention. A dielectric spacer layer 127 may be formed on the substrate surface 105 and on the dielectric layer 125. The dielectric spacer layer 127 may for example be an oxide layer, and may be applied on the substrate 100 by means of a deposition process like e.g. CVD. Contact plugs 150 may be formed which are connected to the conductor portions 131 in the recesses 111, and which extend through the dielectric spacer layer 127 and the dielectric layer 125. Fabrication of the contact plugs 150 may include formation of respective recesses or contact holes in the layers 125, 127 (e.g. by performing a dry etching process), and filling the contact holes with a conductive material. For this purpose, various materials and processes may be considered, for example deposition of a metal by means of CVD, PVD or electroplating, application of a conductive adhesive or a solder material by means of e.g. a dispensing or printing process, etc. These processes may be completed by means of an etching or polishing process in order to remove conductive material outside of the contact holes.

A conductor path 160 may further be formed on the dielectric spacer layer 127 and on the contact plugs 150, thereby making possible an electrical connection between the conductor portions 131 in the recesses 111. The conductor path 160 may run in a direction substantially perpendicular to a direction of the conductor portions 131, as illustrated in FIG. 6. Various fabrication processes and materials may be considered for the conductor path 160. As an example, a conductive layer (comprising e.g. a metal) may be deposited on the spacer layer 127 (e.g. by means of CVD, PVD or electroplating), which is subsequently patterned by means of a lithographic structuring method in order to provide the conductor path 160.

As indicated in the sectional views of FIG. 6, a substrate region 107 of the substrate 100 adjoining to the dielectric layer 120 at the sidewalls and the bottom of the recesses 111 may optionally be provided as doped semiconductor material. In this case, the doped substrate region 107 may serve as counter electrode of the buffer capacitors, thereby allowing for improved buffer characteristics. Formation of the doped substrate region 107 may for example be carried out by means of an ion implant doping process, which is conducted e.g. before formation of the recesses 111 in the substrate region 101. Alternatively, it is also possible to perform the implant doping process in a later process stage.

Process steps in the buffer capacitor region 101 for establishing a connection between the conductor portions 131 may be performed before or after the above described process steps carried out in the array region 102 such as formation of source/drain regions, memory cells and bit lines. It is also possible to “intermix” the aforementioned process steps, i.e. to carry out (a number of) processes alternately or simultaneously in both the substrate regions 101, 102. In this case, with respect to processes carried out in one of the substrate regions 101, 102, the respective other one of the substrate regions 101, 102 may be masked with one or several masking layers, also referred to as block mask.

The fabrication of the integrated circuit may be completed by means of a so-called wafer singulation process. In a process like this, the substrate 100 may be thinned from the backside and diced (not shown), thereby providing a singulated circuit chip including the buffer capacitor region 101 and the array region 102. The buffer capacitors in the region 101 (constituted by the buffer electrodes 131, the dielectric layer 120, and the substrate 100 or the substrate region 107) may be used for stabilizing the voltage supply of the integrated circuit, as indicated in FIG. 6. For this purpose, during operation the conductor path 160 and thus the conductor portions 131 are connected to a first potential V1 of the supply voltage. The conductor path 160 may be part of or may be connected to a power line 165 of the integrated circuit. The substrate 100 or the doped substrate region 107, respectively, is connected to a second potential V2 of the supply voltage. The potential V2 may for example be a ground potential. The potentials V1 and V2 are buffered with respect to one another through the use of the buffer capacitors.

Apart from the depicted five conductor portions 131 in the buffer capacitor region 101 and the depicted five conductor portions 132 in the array region 102, the substrate regions 101, 102 of the integrated circuit may include a different number of conductor portions 131, 132. It is also possible that the numbers of conductor portions 131, 132 in the substrate regions 101, 102 are different from each other. Furthermore, the singulated integrated circuit may comprise more than one buffer capacitor region 101 and more than one array region 102.

The substrate regions 101, 102 may be separated from each other by a distance on the substrate 100 of the integrated circuit. Instead of being spaced apart from each other, the substrate regions 101, 102 may also be adjacent to each other. In this case, it is possible to fabricate an array region comprising word lines and further conductor portions serving as buffer electrodes of buffer capacitors, the further conductor portions being located at the border of the array region and being connected to each other. In this way, a space-saving configuration is made possible on the circuit chip. The further conductor portions may for example be so-called “dummy lines”, which are formed at the edge of an array region when producing word lines, but which are not used as word lines.

As described above, fabrication of the conductor portions 131 in the buffer capacitor region 101 and of the conductor portions 132 in the array region 102 may be performed simultaneously using the same process steps, i.e. that fabrication may be carried out in such a way that the conductor portions 131, 132 substantially comprise the same cross-sectional dimensions. Alternatively, it is possible to modify fabrication steps in one of the substrate regions 101, 102 compared to the other one. This is illustrated with respect to the sectional views of the substrate 100 depicted in FIGS. 7 to 10, wherein the buffer capacitor region 101 is shown on the left hand side, and the array region 102 is shown on the right hand side.

As shown in FIG. 7, the recesses 111 in the buffer capacitor region 101 may comprise a depth D1, and the recesses 112 in the array region 102 may comprise a depth D2, wherein the depth D1 exceeds the depth D2, according to one embodiment of the invention. Consequently, the conductor portions 131 comprise an enlarged thickness and thus an enlarged cross-sectional area compared to the conductor portions 132, which allows for an increased capacitance of the respective buffer capacitors. As an example, the depth D1 may be 350 nm, and the depth D2 may be 250 nm. These specifications are to be considered as examples only and may be replaced by other values.

Fabrication of the recesses 111, 112 having different depths D1, D2 may for example be carried out by performing a first and a second (dry) etching process. In the first etching process, both recesses 111, 112 are simultaneously etched to the depth D2. In the second etching process, the recesses 111 are etched to the depth D1, wherein the array region 102 may for example be masked by means of a block mask in order to prevent further etching of the recesses 112. Alternatively, formation of the recesses 111, 112 comprising different depths D1, D2 may be performed independently from each other. In this case, one of the substrate regions 101, 102 may be masked in the event of an etching process conducted in the other one of the substrate regions 101, 102.

A further structural difference may relate to the thickness of the dielectric layer on sidewalls and the bottom of the recesses 111, 112. As shown in FIG. 8, it is possible to provide a dielectric layer 120 in the recesses 111 of the buffer capacitor region 101, which has a thickness exceeding the thickness of the dielectric layer 120 in the recesses 112 of the array region 102, according to one embodiment of the invention. Due to the increased thickness of the dielectric layer 120′, a potential leakage current occurring between the conductor portions 131 and the surrounding substrate material may be reduced.

Formation of the dielectric layers 120, 120 having a different thickness may for example be carried out by performing a first dielectric formation process (e.g. thermal oxidation, CVD or ISSG) in order to simultaneously form a dielectric layer on sidewalls and a bottom of both the recesses 111 and the recesses 112, removing the dielectric layer in the recesses 112 (by performing e.g. a wet chemistry or dry etching process in the array region 102), and performing a second dielectric formation process (e.g. thermal oxidation, CVD or ISSG) to simultaneously form the dielectric layer 120 in the recesses 112 and to increase the thickness of the dielectric layer in the recesses 111, thus providing the dielectric layer 120′. In the dielectric removal process, the buffer capacitor region 101 may be covered by means of a block mask. Alternatively, it is also possible to carry out formation of the dielectric layers 120, 120 in the recesses 111, 112 independently from each other, wherein one of the substrate regions 101, 102 is masked in the event of a dielectric formation process conducted in the other one of the substrate regions 101, 102.

It is furthermore possible to provide dielectric layers on sidewalls and the bottom of the recesses 111, 112, wherein the dielectric layer in the recesses 112 has a bigger thickness compared to the dielectric layer in the recesses 111 (not shown). In such a variant, the aforementioned process steps may be carried out in a similar way.

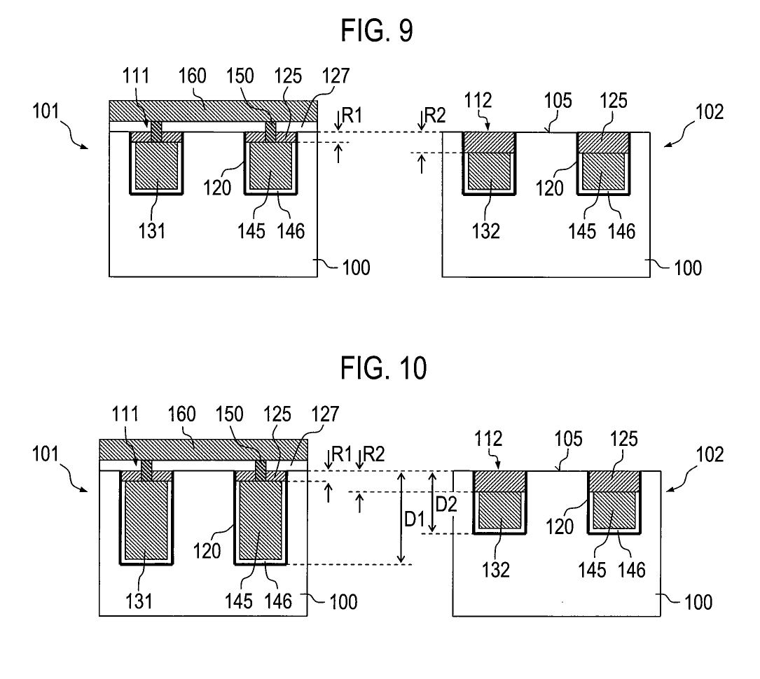

FIG. 9 illustrates another potential structural difference between the buffer capacitor region 101 and the array region 102, according to one embodiment of the invention. Here, the recesses 111, 112 comprise the same depth, but the conductor portions 131 in the buffer capacitor region 101 comprise a bigger thickness compared to the conductor portions 132 in the array region 102. This is due to differing recess etching depths R1, R2, which are applied in the above described recess etching.

As an example, a first recess etching process may be performed after filling the recesses 111, 112 with the barrier layer 146 and the conductive layer 145. In the first recess etching process, a portion of the layers 145, 146 may be simultaneously removed until reaching the recess etching depth R1. Subsequently, a second recess etching process may be performed in order to remove a further portion of the layers 146, 145 in the recesses 112 until reaching the recess etching depth R2. In the second recess etching process, the buffer capacitor region 101 may be masked by means of a block mask. Comparable with the conductor portions 131, 132, the dielectric layer 125 subsequently applied in the upper recess section of the recesses 111, 112 comprises different thicknesses, namely R1 and R2.

Alternatively, it is also possible to carry out recess etching processes in the substrate regions 101, 102 independently from each other. In this case, one of the substrate regions 101, 102 may be masked in the event of a recess etching process carried out in the other one of the substrate regions 101, 102.

The different variants described with respect to FIGS. 7 to 9 may furthermore be combined with each other. An example is shown in FIG. 10. Here, the recesses 111, 112 comprise different depths D1, D2, and different recess etching depths R1, R2 are provided, so that the thickness and the cross-sectional area of the conductor portions 131 is relatively large compared to that of the conductor portions 132, according to one embodiment of the invention. It is furthermore possible to combine the different variants depicted in FIGS. 7, 9 and 10 with the variant of different thicknesses of dielectric layers 120, 120 illustrated with respect to FIG. 8 (not shown).

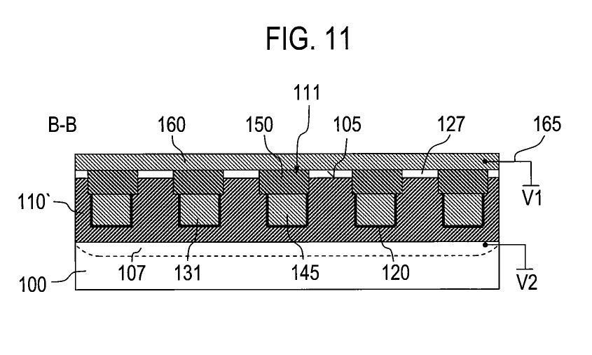

In the method illustrated with respect to FIGS. 1 to 6, isolation regions (e.g. the isolation regions 110) are fabricated in the array region 102, whereas the buffer capacitor region 101 is not provided with such isolation regions. It is however possible to additionally provide an isolation region or line 110 also in the buffer capacitor region 101, as shown in the sectional view of FIG. 11. Here, the isolation region 110 is located in the area of the conductor path 160 and serves for preventing a short-circuit of the buffer capacitors. A short-circuit may result from removing or damaging a portion of the dielectric layer 120 due to an incorrect etching process carried out for fabricating contact holes for the contact plugs 150. As a consequence, the contact plugs 150 may have a diameter which is similar to or exceeds the width of a conductor portion 131, as shown in FIG. 11, or may even be formed as a contiguous structure underlying the conductor path 160 (not shown), thereby making possible an electrical connection between the conductor portion 131 and the surrounding substrate material. Such a connection may be prevented by means of the isolation region 110 in the area of the conductor path 160.

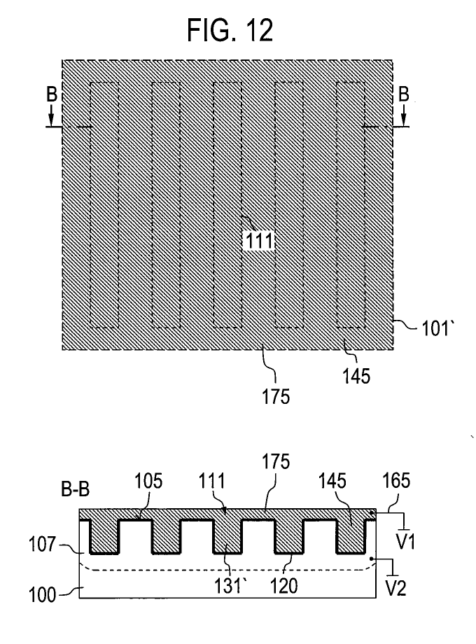

FIG. 12 shows a schematic plan view and a sectional view of a buffer capacitor region 101 of the substrate 100 for illustrating another variant of the buffer capacitors, according to one embodiment of the invention. As shown, the buffer capacitors comprise conductor portions 131 serving as buffer electrodes which completely fill recesses 111. A connection device such as a plane electrode portion 175 may connect the conductor portions 131 to each other.

Fabrication of the buffer capacitors may include process steps as described above, i.e. formation of recesses 111 in the substrate 100 extending from the substrate surface 105, formation of a dielectric layer 120 on sidewalls and a bottom of the recesses 111 and on the substrate surface 105 outside the recesses 111, and deposition of a conductive layer 145. It is additionally possible to provide a barrier layer between the dielectric layer 120 and the conductive layer 145 (not shown). These process steps may again be carried out simultaneously in a further (adjacent or separate) substrate region for producing word lines, for example the substrate region 102 of FIGS. 1 to 5. In this case, it is furthermore possible to modify process steps like formation of recesses and/or formation of a dielectric layer, thus providing recesses of different depths and/or dielectric layers in the recesses having different thicknesses with respect to the region 101′ and the further substrate region.

After application of the conductive layer 145, however, recess etching process may not be performed in the buffer capacitor region 101′. In this case, the conductive layer 145 may therefore provide conductor portions 131′ filling the recesses 111, and the plane electrode portion 175 on top of and being connected to the conductor portions 131′. In this way fabrication of the conductor portions 131′ being connected to each other is made possible with little time and effort. In order to provide the electrode portion 175 with a smooth surface, it is optionally possible to perform a polishing process like for example CMP after deposition of the conductive layer 145.

As further indicated in FIG. 12, the substrate 100 may again be provided with a doped substrate region 107. When operating the respective singulated circuit chip comprising the buffer capacitor region 101′, the electrode 175 and thus the conductor portions 131 are connected to a first potential V1, and the substrate 100 or the doped substrate region 107 of the same is connected to a second potential V2 (e.g. a ground potential) of the supply voltage. The electrode 175 may be part of or be connected to a power line 165 of the integrated circuit, as shown in FIG. 12. Apart from establishing a connection between the conductor portions 131′, the plane electrode portion 175 may provide an additional capacitance at the substrate surface 105.

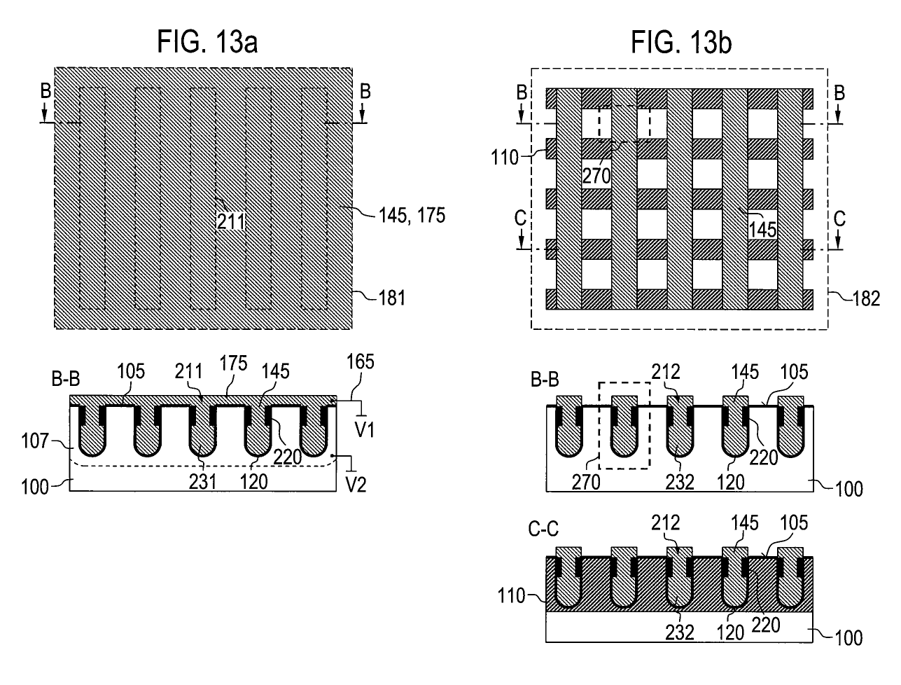

FIGS. 13a and 13b show plan views and sectional views of the substrate 100 for illustrating a further variant of a buffer capacitor region 181 and of an array region 182 of an integrated circuit, according to one embodiment of the invention. The substrate regions 181, 182 may again be separated from each other on the substrate 100, or may be located adjacent to each other. Corresponding to the method described in conjunction with the preceding figures, a number of process steps such as for example formation of recesses, formation of a dielectric layer in the recesses and deposition of a conductive layer may be simultaneously performed in both of the substrate regions 181, 182. With regard to further details concerning for example applied processes and materials, reference is made to the above information.

Recesses 211 may be formed in the buffer capacitor region 181, and recesses 212 may be formed in the array region 182 of the substrate 100, the recesses 211, 212 extending from a surface 105 of the substrate 100 and being parallel to each other. A doped substrate region 107 may optionally be formed in the buffer capacitor region 181 beforehand. The recesses 211, 212 may have the form of grooves, and—in a cross-sectional view—a U-shaped bottom. The recesses 212 in the array region 182 furthermore run perpendicular to and penetrate isolation regions 110 (which are fabricated beforehand). It is optionally possible to fabricate the recesses 211, 212 with different depths, so that e.g. the depth of the recesses 211 exceeds the depth of the recesses 212 (not shown).

A dielectric layer 120 may be formed on sidewalls and a bottom of the recesses 211, 212 and on the substrate surface 105 outside the recesses 211, 212. Dielectric spacers 220 may additionally be formed in an upper section of the recesses 211, 212 on the dielectric layer 120. Formation of spacers 220—like formation of the dielectric layer 120—may be performed simultaneously in the substrate regions 181, 182. It is optionally possible to provide the dielectric layer 120 in the substrate regions 181, 182 with different thicknesses (not shown).

A conductive layer 145 may furthermore be formed on the substrate 100 in a large-area manner. A barrier layer may optionally be provided between the dielectric layer 120 and the conductive layer 145 (not shown). The conductive layer 145 fills the recesses 211, 212, thereby providing conductor portions 231 in the buffer capacitor region 181 and conductor portions 232 in the array region 182. The conductor portions 231 serve as buffer electrodes of buffer capacitors, wherein the substrate 100 or the doped substrate region 107 of the same represents the counter electrode of the capacitors. The conductor portions 232 serve as word lines and gate electrodes.

In the buffer capacitor region 181, the conductive layer 145 may furthermore provide a plane electrode portion 175 on top of and being connected to the conductor portions 231. The electrode portion 175 may serve for an additional capacitance at the substrate surface 105. In order to provide the electrode portion 175 with a smooth surface, it is optionally possible to perform a polishing process after deposition of the conductive layer 145. The electrode portion 175 may be part of or be connected to a power line 165 of the integrated circuit, as shown in FIG. 13a.

In the array region 182, the conductive layer 145 may furthermore be patterned, for example by means of a lithographic structuring method. In this way, the conductor portions 231 are disconnected from each other and comprise portions extending above the substrate surface 105. In areas between the isolation regions 110, the conductor portions 232 serve as gate electrodes of transistors. For way of illustration, the plan view of the array region 182 depicted in FIG. 13b indicates a respective active area of a transistor 270. The transistor 270 may for example be a so-called RCAT device (Recessed Channel Array Transistor). For completion of transistors 270 in the array region 182, source and drain regions are formed in the substrate 100 (not shown). Moreover, bit lines and memory elements may be fabricated above the transistors 270 in the array region 182 (not shown).

When operating the respective singulated integrated circuit including the substrate regions 181, 182, the plane electrode portion 175 and thus the conductor portions 231 may be connected to a first potential V1 of a supply voltage. The substrate 100 or the doped substrate region 107 of the same may be connected to a second potential V2 (e.g. a ground potential) of the supply voltage.

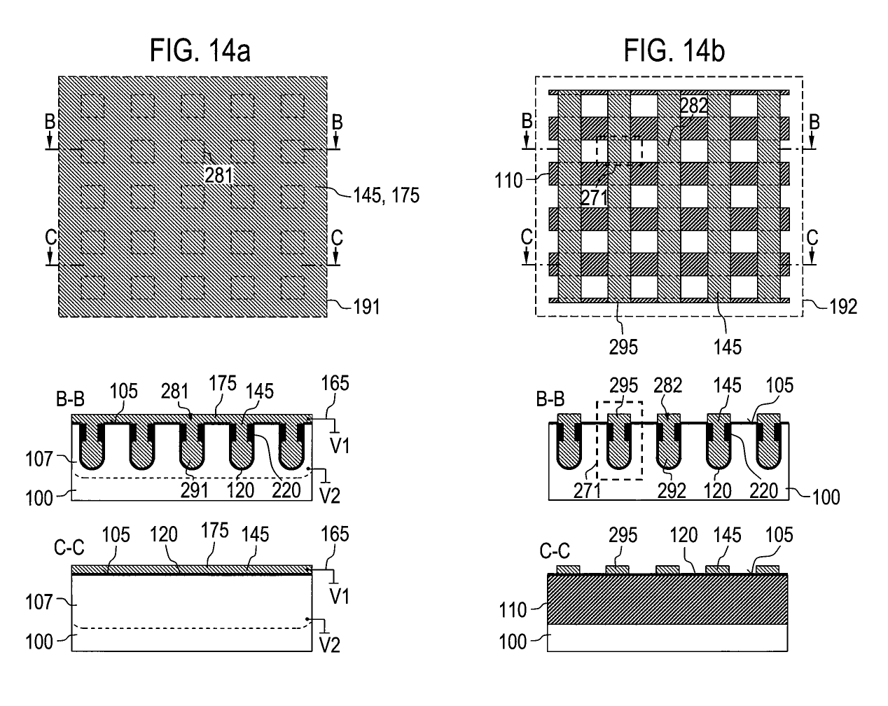

FIGS. 14a and 14b show schematic plan views and sectionals views of the substrate 100 for illustrating a further variant of a buffer capacitor region 191 and of an array region 192 of an integrated circuit, according to one embodiment of the invention. Instead of recesses having the form of trenches, finger-like recesses 281, 282 are formed in the substrate 100 extending from the substrate surface 105. The recesses 281, 282 may for example comprise a substantially rectangular base area as indicated in the plan view of FIGS. 14a and 14b, or alternatively a circular or elliptic base area (not shown). The recesses 281, 282 may furthermore comprise a U-shaped bottom, as illustrated in the cross-sectional views of FIGS. 14a and 14b.

The further configuration of the buffer capacitor region 191 and of the array region 192 substantially corresponds to that of the substrate regions 181, 182 of FIGS. 13a and 13b, including a dielectric layer 120, dielectric spacers 220 in an upper section of the recesses 281, 282, and a conductive layer 145. Therefore, with regard to details concerning process steps carried out in the substrate regions 191, 192, reference is made to the above information. A number of processes may again be performed simultaneously in both substrate regions 191, 192.

The conductive layer 145 may fill the recesses 291, 292, thereby providing buffer electrodes 291 in the buffer capacitor region 191, and gate electrodes 292 for transistors 271 in the array region 192. In the array region 192, the conductive layer 145 may further provide a plane electrode portion 175 on top of and being connected to the buffer electrodes 291. The plane electrode portion 175 may again be part of or be connected to a power line 165 of the integrated circuit. A doped semiconductor region 107 may be provided in the buffer capacitor region 191, as well. With respect to the array region 192, the conductive layer 145 may furthermore be patterned in order to provide separate word lines 295 above the recesses 282, the word lines 295 being connected to the gate electrodes 292 in the recesses 282. The respective transistors 271 may again be RCAT transistors.

When operating the respective singulated integrated circuit chip including the substrate regions 191, 192, the plane electrode portion 175 and thus the conductor portions 291 may be connected to a first potential V1 of a supply voltage. The substrate 100 or the doped substrate region 107 is connected to a second potential V2 (e.g. a ground potential) of the supply voltage.

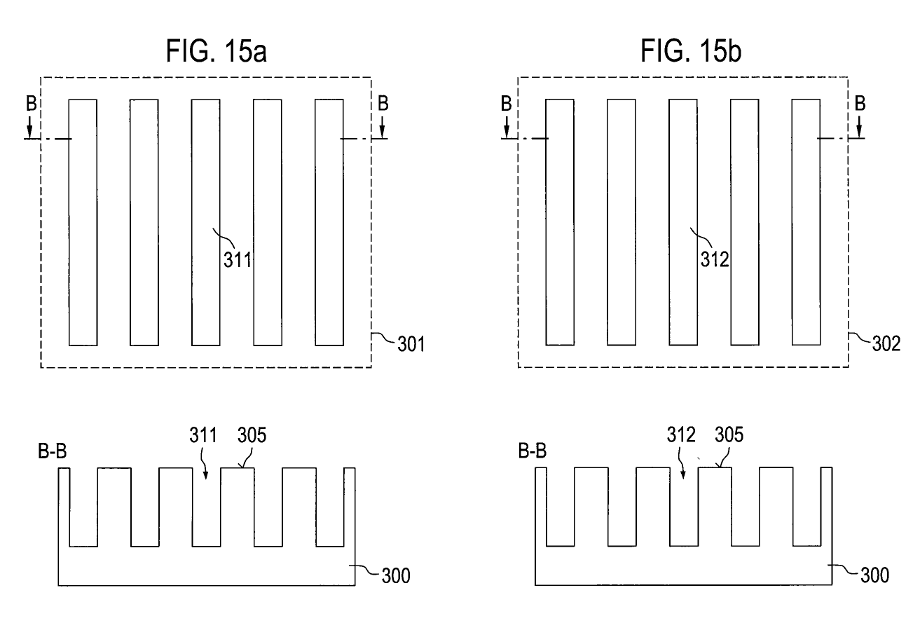

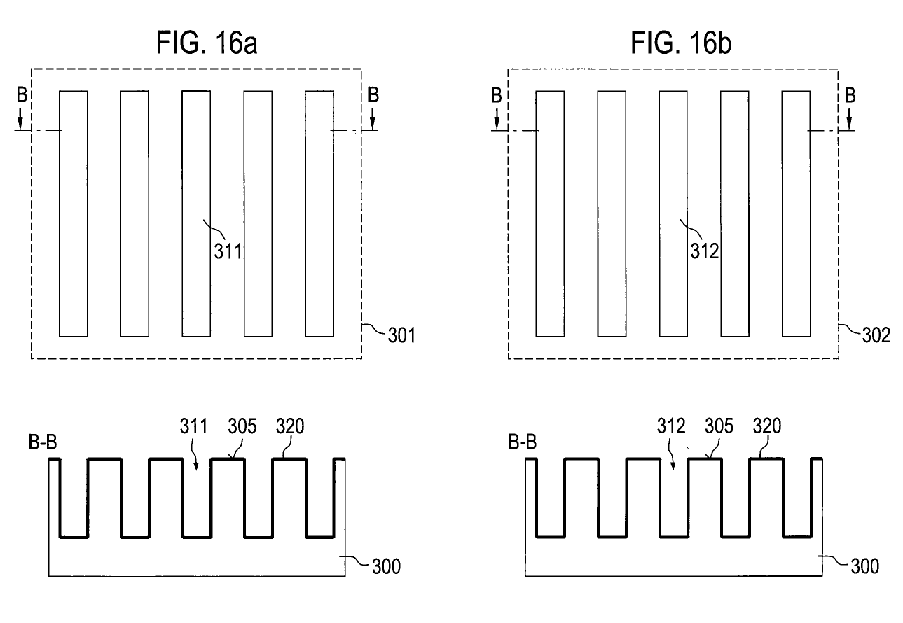

The following FIGS. 15 to 20 show schematic plan views and sectional views of a substrate 300 for illustrating steps of a method for fabricating buffer capacitors together with bit lines of an integrated circuit, according to one embodiment of the invention. The substrate 300 may comprise a semiconductor material such as for example silicon, and may be a semiconductor wafer. The figures include plan views (at the top) and cross-sectional views of a buffer capacitor region 301 (FIGS. 15a to 20a on the left hand side) and of an array region 302 (FIGS. 15b to 20b on the right hand side).

As illustrated in FIGS. 15a and 15b, recesses 311 may be formed in the buffer capacitor region 301, and recesses 312 may be formed in the array region 302 of the substrate 300, according to one embodiment of the invention. The recesses 311, 312, which have the form of trenches or grooves, extend from a surface 305 of the substrate 300 and run substantially parallel to each other and to the substrate surface 305.

The recesses 311, 312 may comprise the same cross-sectional dimensions and may be fabricated simultaneously by performing the same process steps in the substrate regions 301, 302. Fabrication of the recesses 311, 312 may for example be performed by means of a dry etching process. In order to define the lateral structure of the recesses 311, 312, one or several patterned masking layers may be applied on the substrate surface 305, which are removed after completing the etching process (not shown). The recesses 311, 312 may for example have a depth of several 100 nm (e.g. 200-600 nm) and a length of several μm. These specifications are to be considered as examples only and may be replaced by other values.

Thereafter, as illustrated in FIGS. 16a and 16b, a dielectric layer 320 may be formed on sidewalls and a bottom of each of the recesses 311, 312, according to one embodiment of the invention. The dielectric layer 320, which may be simultaneously formed in the recesses 311, 312, may further be formed on the substrate surface 305 outside the recesses 311, 312. The dielectric layer 320 may for example be a silicon oxide layer. Various other materials may also be considered for the dielectric layer 320, such as e.g. high-k dielectrics. Formation of the dielectric layer 320 may for example be carried out by means of a deposition process like for example CVD (e.g. a TEOS process). Alternatively, a thermal oxidation process or an ISSG process may be carried out for this purpose.

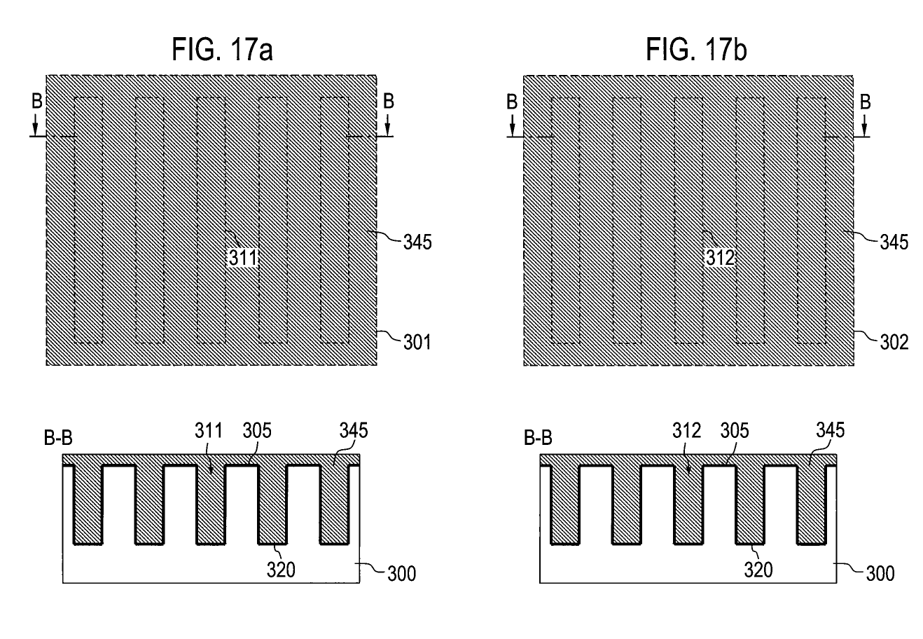

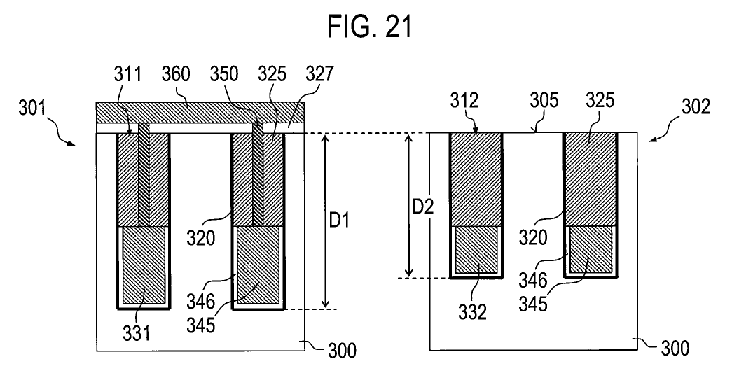

Subsequently, as shown in FIGS. 17a and 17b, a conductive layer 345 may be deposited on the substrate 100 in a large-area manner, thereby filling both the recesses 311 and the recesses 312, according to one embodiment of the invention. The conductive layer 345 may be directly formed on the dielectric layer 320, or alternatively on a barrier layer 346 which is deposited on the dielectric layer 320 beforehand (cf. FIGS. 21 to 25). In order to deposit the layers 345, 346 in the substrate regions 301, 302, deposition processes like for example PVD, CVD and electroplating may be carried out.

Potential materials for the conductive layer 345 are for example metals like e.g. tungsten, copper, aluminum, nickel, gold and silver, and materials like for example doped poly silicon and carbon. Materials such as titanium nitride, titanium tungsten, titanium, tantalum, tantalum nitride, ruthenium and nickel phosphorus may also be considered for the conductive layer 345. The conductive layer 345 may comprise these materials individually or in the form of material mixes or alloys. It is also possible to provide sublayers of different materials in the conductive layer 345. Examples of materials for the barrier layer 346 are titanium nitride, titanium tungsten, titanium, tantalum and tantalum nitride. Apart from these materials, various other materials may be considered for the conductive layer 345 and for the barrier layer 346.

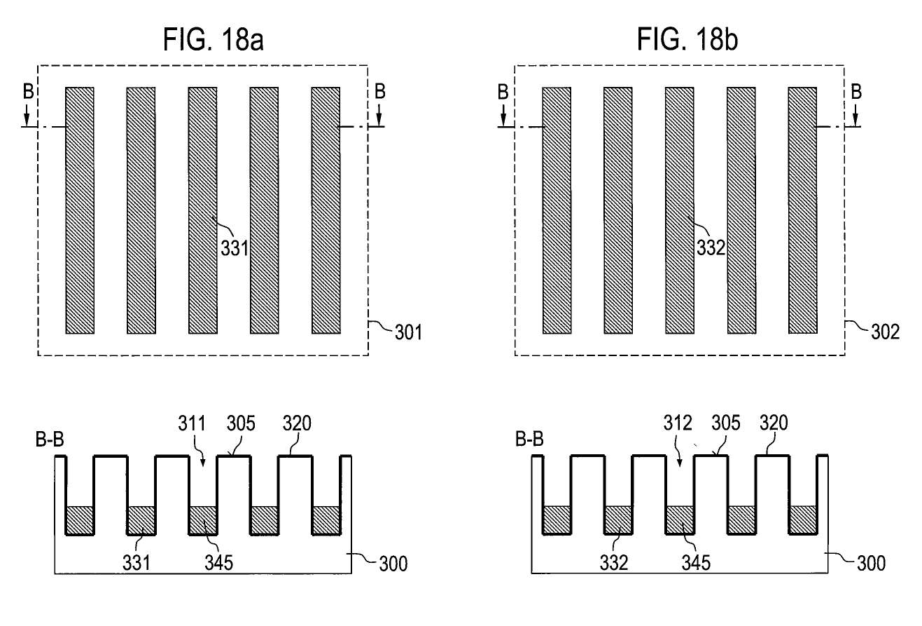

Afterwards, as illustrated in FIGS. 18a and 18b, a portion of the conductive layer 345—and of the barrier layer 346 if provided—may be removed in such a way that the layers 345, 346 remain in a lower recess section of the recesses 311, 312, thereby providing conductor portions 331, 332, according to one embodiment of the invention. Partially removing the layers 345, 346 may be simultaneously performed in the substrate regions 301, 302, for example by means of a dry etching process (recess etching). Optionally, a polishing process like for example CMP may be carried out beforehand, wherein polishing is stopped when reaching the dielectric layer 320 outside the recesses 311, 312 at the substrate surface 305. The conductor portions 331, 332—like the recesses 311, 312—run substantially parallel to each other and to the substrate surface 305. The conductor portions 331 in the buffer capacitor region 301 constitute electrodes of buffer capacitors, whereas the conductor portions 332 in the array region 302 serve as bit lines, as described further below.

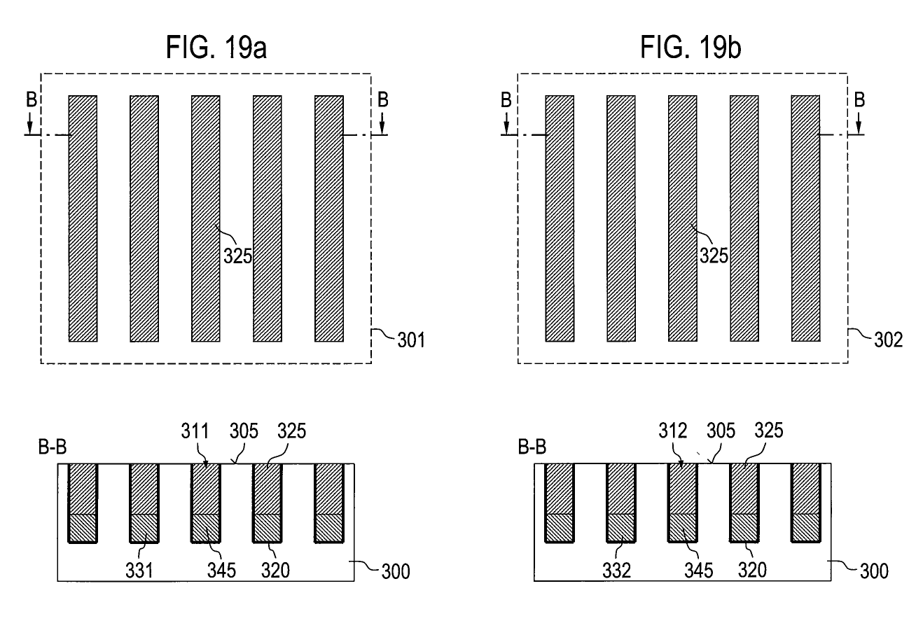

Subsequently, as shown in FIGS. 19a and 19b, a further dielectric layer 325 may be formed in an upper recess section of the recesses 311, 312 on the conductor portions 331, 332, thereby filling the recesses 311, 312, according to one embodiment of the invention. The further dielectric layer 325 may for example be an oxide layer, and may be simultaneously formed in the substrate regions 301, 302. As an example, the dielectric layer 325 may be deposited on the substrate 300 in a large-area manner by means of e.g. a CVD process, and by subsequently performing a polishing process like e.g. CMP, a portion of the dielectric layer 325 outside of the recesses 311, 312 may be removed so that the dielectric layer 325 only remains in the upper recess section of the recesses 311, 312. In the course of the polishing process, also a portion of the dielectric layer 320 outside of the recesses 311, 312 may be removed, thereby exposing the substrate surface 305 as shown in the sectional views of FIGS. 19a and 19b.

Afterwards, further method steps may be performed in the buffer capacitor region 301 and in the array region 302. With respect to the buffer capacitor region 301, the conductor portions 331 may serve as electrodes of buffer capacitors. At this, the counter electrode of the buffer capacitors may be constituted by the semiconductor material of the substrate 300 which is separated from the conductor portions 331 by the dielectric layer 320 in the recesses 311. In order to provide a parallel circuit of buffer capacitors, the conductor portions 331 are furthermore electrically connected to each other.

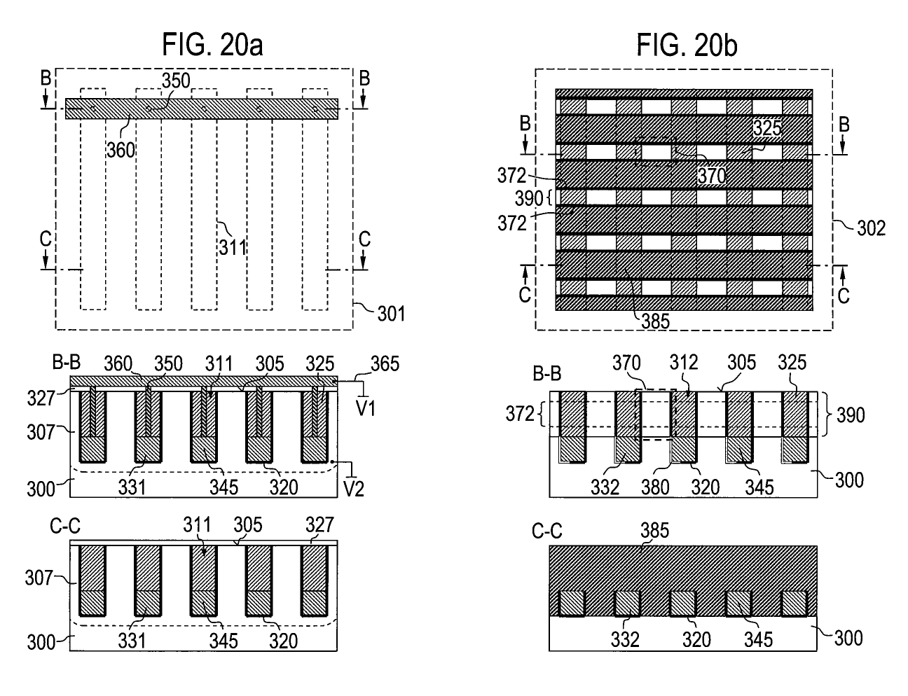

For way of illustration, FIG. 20a depicts a possible configuration for connection of conductor portions 331 in the buffer capacitor region 301, according to one embodiment of the invention. A dielectric spacer layer 327 is formed on the substrate surface 305 and on the dielectric layer 325. The dielectric spacer layer 327 may for example be an oxide layer, and may be applied on the substrate 300 by means of a deposition process like for example CVD. Contact plugs 350 may be formed which are connected to the conductor portions 331 in the recesses 311 and which extend through the dielectric spacer layer 327 and the dielectric layer 325. Fabrication of the contact plugs 350 may be carried out by forming respective contact holes in the layers 325, 327 (e.g. by performing a dry etching process), and filling the contact holes with a conductive material (e.g. by depositing a metal by means of CVD, PVD or electroplating, or by applying a conductive adhesive or a solder material by means of e.g. a dispensing or printing process). Additionally, an etching or polishing process may be carried out in order to remove conductive material outside of the contact holes.

In order to make possible an electrical connection between the conductor portions 331 in the recesses 311, a conductor path 360 may be further formed on the dielectric spacer layer 327 and on the contact plugs 350, which may run in a direction substantially perpendicular to the conductor portions 331. Various fabrication processes and materials may be considered for the conductor path 360. This includes for example deposition of a conductive layer (e.g. a metal layer) on the spacer layer 327 (e.g. by means of CVD, PVD or electroplating), and patterning the conductive layer by means of a lithographic structuring method to provide the conductor path 360.

As indicated in the sectional views of FIG. 20a, a substrate region 307 of the substrate 300 adjoining to the dielectric layer 320 at the recesses 311 may optionally be provided with a doped semiconductor material in order to provide a counter electrode for the buffer capacitors. In this way the buffer characteristics may be improved. Formation of the doped substrate region 307 may for example be performed by means an ion implant doping process, which is conducted e.g. before formation of the recesses 311. Alternatively, it is possible to perform the implant doping process in a later process stage.

With respect to the array region 302, the conductor portions 332 serve as bit lines. Due to the arrangement in the recesses 312, the conductor portions 332 may also be referred to as “buried” bit lines. As illustrated in FIG. 20b, fins 390 including active areas of transistors 370 and isolation plugs arranged adjacent to each other may be provided above the bit lines 332. The isolation plugs are constituted by the dielectric layers 320, 325. Furthermore, word lines 372 may be provided on both sides of the fins 390, wherein gate dielectric layers are disposed between the word lines 372 and the fins 390 (not shown). The fins 390 and the word lines 372 run substantially perpendicular to the bit lines 332. Isolation regions or lines 385 are provided between the fins 390.

Fabrication of such components in the array region 302 may include removing substrate material and portions of the dielectric layers 320, 325 in order to form respective recesses for the isolation regions 385. Source and drain regions may be formed in the active areas 370. Portions of the dielectric layer 320 at the bit lines 332 below the fins 390 are removed and replaced by single sided bit line contacts 380, which make possible a connection of the bit lines 332 to the active areas of the transistors 370 (cf. cross-section B-B of FIG. 19b). Afterwards, the gate dielectric layers and word lines 372 are formed at the sides of the fins 390, and the recesses between the fins 390 are filled with a dielectric material in order to provide the isolation regions 385. As shown in the cross-sectional view C-C of FIG. 20b, the isolation regions 385 may extend from the surface of the substrate 300 to the bottom of the bit lines 332.

Moreover, further methods steps may be performed in the array region 302, including for example fabrication of memory elements above the transistors 370 (not shown). In this case, the transistors 370 may serve as selection transistors in order to connect memory elements to respective bit lines 332 when operating the integrated circuit.

Process steps carried out in the buffer capacitor region 301 to connect the conductor portions 331 to each other may be performed before or after the above described process steps carried out in the array region 302 such as formation of isolation regions 385 and word lines 372. It is also possible to carry out (a number of) processes alternately or simultaneously in both the substrate regions 301, 302. At this, with respect to processes carried out in one of the substrate regions 301, 302, the respective other one of the substrate regions 301, 302 may be masked with a block mask.

The fabrication of the integrated circuit may be completed by means of a wafer singulation process, thereby providing a singulated circuit chip including the buffer capacitor region 301 and the array region 302. The buffer capacitors in the buffer capacitor region 301 (constituted by the buffer electrodes 331, the dielectric layer 320, and the substrate 300 or the substrate region 307) may be used for stabilizing the voltage supply of the integrated circuit, as indicated in FIG. 20a. During operation, the conductor path 360 and thus the conductor portions 331 may be connected to a first potential V1 of the supply voltage, and the substrate 300 or the doped substrate region 307, respectively, may be connected to a second potential V2 (e.g. a ground potential) of the supply voltage. At this, the conductor path 360 may be part of or be connected to a power line 365 of the integrated circuit.

Apart from the depicted five conductor portions 331 and five conductor portions 332, the substrate regions 301, 302 of the integrated circuit may include a different number of conductor portions 331, 332. The numbers of conductor portions 331, 332 in the substrate regions 301, 302 may also be different from each other. Furthermore, the singulated integrated circuit may comprise more than one buffer capacitor region 301 and more than one array region 302. The substrate regions 301, 302 may either be separated from each other by a distance on the substrate 300, or alternatively be adjacent to each other. It is for example possible to fabricate an array region comprising bit lines and further conductor portions serving as buffer electrodes, the further conductor portions being located at the border of the array region and being connected to each other. This allows for a space-saving configuration on the circuit chip. The further conductor portions may for example be “dummy lines”, which are formed at the edge of an array region when producing bit lines, but which are not used as bit lines.

As described above, fabrication of the conductor portions 331, 332 may be performed simultaneously in the substrate regions 301, 302 using the same process steps, so that the conductor portions 331, 332 substantially comprise the same cross-sectional dimensions. Alternatively, it is possible to modify fabrication steps in one of the substrate regions 301, 302 compared to the other one. This is illustrated in the sectional views of the substrate 300 depicted in FIGS. 21 to 24, wherein the buffer capacitor region 301 is shown on the left hand side, and the array region 302 on the right hand side, according to one embodiment of the invention.

As shown in FIG. 21, the recesses 311 in the buffer capacitor region 301 may comprise a thickness D1 exceeding a thickness D2 of the recesses 312 in the array region 302, according to one embodiment of the invention. The conductor portions 331 may thus comprise an enlarged cross-sectional area compared to the conductor portions 332, which allows for an increased capacitance of the respective buffer capacitors. As an example, the depth 1 my be 1 μm, and the depth D2 may be in the range between 500 and 800 nm. These specifications are to be considered as examples only, and may be replaced by other values.

Fabrication of the recesses 311, 312 having different depths D1, D2 may for example be carried out by performing a first and a second (dry) etching process. In the first etching process, both recesses 311, 312 are simultaneously etched to the depth D2. In the second etching process, the recesses 311 are etched to the depth D1, wherein the array region 302 may for example be masked by means of a block mask in order to prevent further etching of the recesses 312. Alternatively, it is possible to carry out formation of the recesses 311, 312 independently from each other, wherein one of the substrate regions 301, 302 is masked in the event of an etching process conducted in the other one of the substrate regions 301, 302.

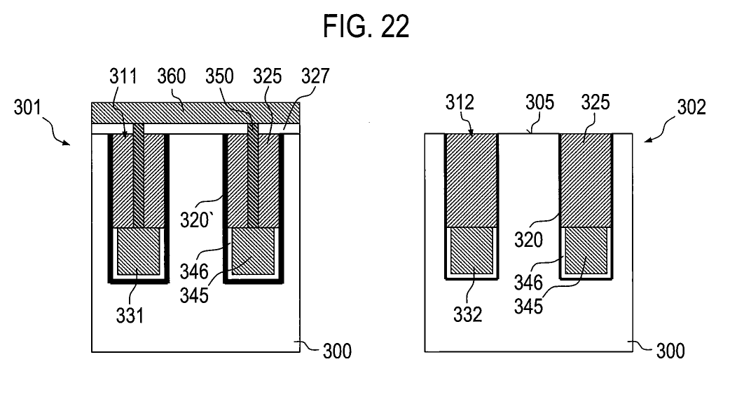

As shown in FIG. 22, it is furthermore possible to provide a dielectric layer 320 in the buffer capacitor region 301, which has a thickness exceeding the thickness of the dielectric layer 320 in the array region 302, according to one embodiment of the invention. This allows for reduction of a potential leakage current occurring between the conductor portions 331 and the surrounding substrate material. Formation of the dielectric layers 320, 320 having a different thickness may for example be carried out by performing a first dielectric formation process (e.g. thermal oxidation, CVD or ISSG) in order to simultaneously form a dielectric layer at the recesses 311, 312, removing the dielectric layer at the recesses 312 (by performing e.g. a wet chemistry or dry etching process), and performing a second dielectric formation process (e.g. thermal oxidation, CVD or ISSG) to simultaneously form the dielectric layer 320 at the recesses 312 and to increase the thickness of the dielectric layer at the recesses 311, thus providing the dielectric layer 320′. In the dielectric removal process, the buffer capacitor region 301 may be covered by means of a block mask. Formation of the dielectric layers 320, 320 may alternatively be carried out independently from each other, wherein one of the substrate regions 301, 302 is masked in the event of a dielectric formation process conducted in the other one of the substrate regions 301, 302. The aforementioned process steps may also be carried out in a similar way in order to provide dielectric layers at the recesses 311, 312, wherein the dielectric layer at the recesses 312 has a bigger thickness compared to the dielectric layer at the recesses 311 (not shown).

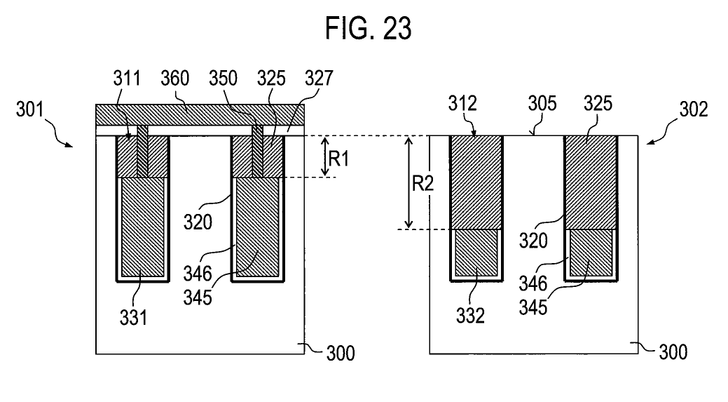

As indicated in FIG. 23, different thicknesses of the conductor portions 331, 332 may also be provided by carrying out the above described recess etching with different recess etching depths R1, R2, according to one embodiment of the invention. As an example, a first recess etching process may be performed (following filling the recesses 311, 312 with the barrier layer 346 and the conductive layer 345) in order to simultaneously remove a portion of the layers 345, 346 in the recesses 311, 312 until reaching the recess etching depth R1. Subsequently, a second recess etching process may be performed in order to remove a further portion of the layers 346, 345 in the recesses 312 until reaching the recess etching depth R2. In the second recess etching process, the buffer capacitor region 301 may be masked by means of a block mask. Alternatively, recess etching processes may be carried out independently from each other in the substrate regions 301, 302, wherein one of the substrate regions 301, 302 is masked in the event of a recess etching process carried out in the other one of the substrate regions 301, 302.

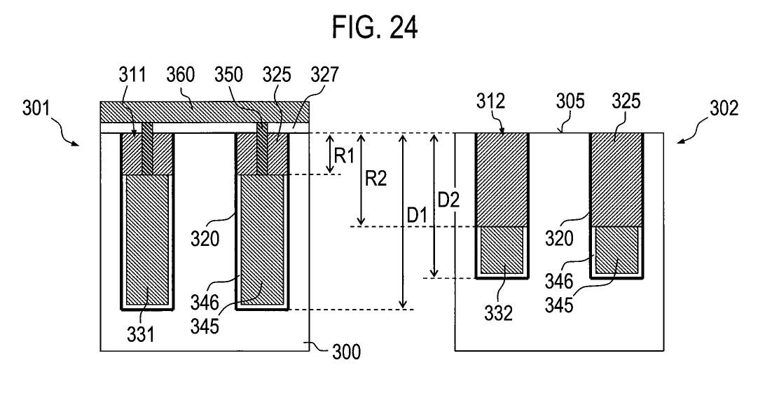

The different variants illustrated with respect to FIGS. 21 to 23 may furthermore be combined with each other. An example is shown in FIG. 24. Here, both the recesses 311, 312 comprise different depths D1, D2, and different recess etching depths R1, R2 are provided, according to one embodiment of the invention. It is furthermore possible to combine the different variants depicted in FIGS. 21, 23 and 24 with the variant of different thicknesses of dielectric layers 320, 320 illustrated with respect to FIG. 22 (not shown).

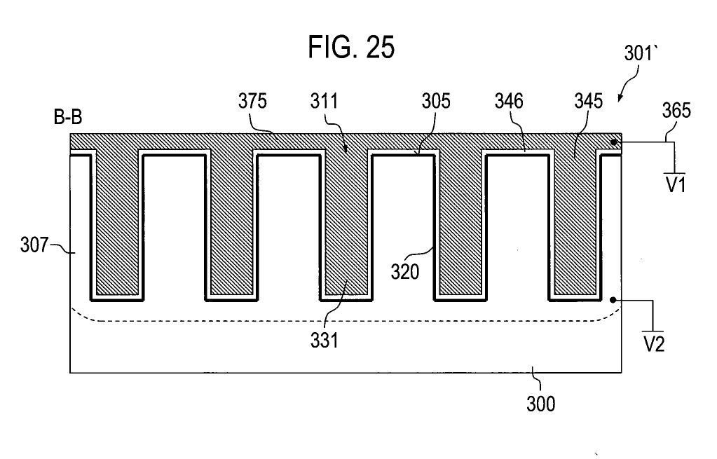

FIG. 25 shows a schematic sectional view of the substrate 300 for illustrating a variant of a buffer capacitor region 301′, according to one embodiment of the invention. Here, no recess etching process is performed after application of the conductive layer 345 (cf. FIG. 17). Consequently, the conductive layer 345 and the barrier layer 346 may fill the recesses 311, thereby providing conductor portions 331 serving as buffer electrodes of the buffer capacitors. The conductive layer 345 furthermore provides a plane electrode portion 375 on top of and being connected to the conductor portions 331 in the recesses 311. In order to provide the electrode portion 375 with a smooth surface, it is optionally possible to perform a polishing process like for example CMP after deposition of the conductive layer 345. Besides making possible an electrical connection of the conductor portions 331 to each other, the plane electrode portion 375 may also provide an additional capacitance at the substrate surface 305.

As further indicated in FIG. 25, the substrate 300 may again be provided with a doped substrate region 307. When operating the respective singulated circuit chip comprising the buffer capacitor region 301 (and an array region 302 if provided), the electrode 375 and thus the conductor portions 331 may be connected to a first potential V1, and the substrate 300 or the doped substrate region 307 of the same may be connected to a second potential V2 (e.g. a ground potential) of the supply voltage. The electrode portion 375 may be part of or be connected to a power line 365 of the integrated circuit.

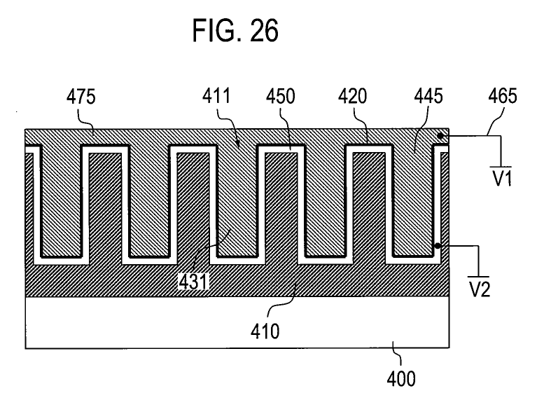

FIG. 26 shows a schematic sectional of a substrate 400 for illustrating another variant of buffer capacitors, which may also be fabricated together with word lines or bit lines, according to one embodiment of the invention. The substrate 400, which may for example be a semiconductor wafer, may comprise a relatively thick dielectric or insulating layer 410 (e.g. an oxide layer). Recesses 411 may be formed in the dielectric layer 410 extending from a surface of the layer 410, wherein the depth of the recesses 411 may be smaller than the thickness of the dielectric layer 410. The recesses 411 may for example be parallel trenches or grooves, and may have a depth of e.g. several 100 nm and a length of e.g. several μm. These specifications for depth and length are to be considered as examples only and may be replaced by other values. Alternatively, the recesses 411 may also have the shape of defined openings, comparable to the recesses 281 of FIG. 14.

After formation of the recesses 411, a first conductive layer 450, a dielectric layer 420 and a second conductive layer 445 may be successively deposited on the dielectric layer 410, respectively, thereby filling the recesses 411. Both conductive layers 450, 445 may for example be metal layers. With respect to formation of the recesses 411, deposition of the layers 450, 420, 445, and potential materials for the layers 450, 420, 445, reference is made to the above information. This also applies to an optional barrier layer, which may be provided as well (not shown).

The conductive layer 445 may provide conductor portions or electrodes 431, respectively, in the recesses 411, and a plane electrode portion 475 on top. In order to provide the electrode portion 475 with a smooth surface, it is optionally possible to perform a polishing process like for example CMP after deposition of the conductive layer 445. The electrodes 431 and the conductive layer 450 (serving as counter electrode) constitute buffer capacitors. By means of the plane electrode portion 475, the electrodes 431 in the recesses 411 may be connected to each other. When operating the respective singulated circuit chip comprising the depicted buffer capacitors, the electrode portion 475 and thus the electrodes 431 may be connected to a first potential V1, and the conductive layer 450 is connected to a second potential V2 (e.g. a ground potential) of a supply voltage. Here, the electrode portion 475 may be part of or be connected to a power line 465 of the integrated circuit, as indicated in FIG. 26.

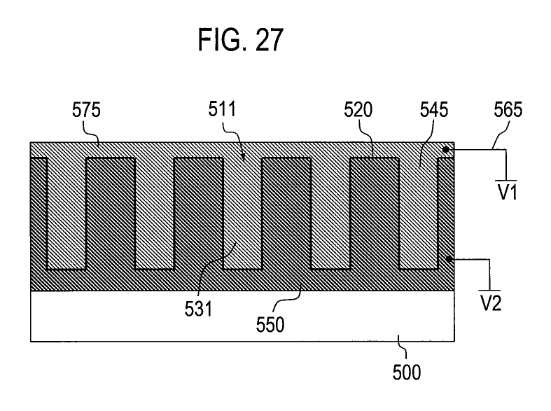

FIG. 27 shows a schematic sectional of a substrate 500 for illustrating yet another variant of buffer capacitors, which may also be fabricated together with word lines or bit lines, according to one embodiment of the invention. The substrate 500, which may for example be a semiconductor wafer, may comprise a relatively thick conductive layer 550 (e.g. metal layer). Recesses 511 may be formed in the conductive layer 550 extending from a surface of the layer 550, wherein the depth of the recesses 511 may be smaller than the thickness of the conductive layer 550. The recesses 511 may for example be parallel trenches or grooves, and may have a depth of e.g. several 100 nm and a length of e.g. several μm. These specifications for depth and length are to be considered as examples only and may be replaced by other values. The recesses 511 may alternatively have the shape of defined openings, comparable to the recesses 281 of FIG. 14.

After formation of the recesses 511, a dielectric layer 520 and a further conductive layer (e.g. a metal layer) 545 may be successively deposited on the conductive layer 550, thereby filling the recesses 511. With respect to formation of the recesses 511, deposition of the layers 520, 545 and potential materials for the layers 520, 545, reference is made to the above information. This also applies to an optional barrier layer, which may be provided as well (not shown).

The conductive layer 545 may provide conductor portions or electrodes 531, respectively, in the recesses 511, and a plane electrode portion 575 on top. In order to provide the electrode portion 575 with a smooth surface, it is optionally possible to perform a polishing process like for example CMP after deposition of the conductive layer 545. The electrodes 531 and the conductive layer 550 (serving as counter electrode) constitute buffer capacitors. By means of the plane electrode portion 575, the electrodes 531 in the recesses 511 may be connected to each other. When operating the respective singulated circuit chip comprising the depicted buffer capacitors, the electrode portion 575 and thus the electrodes 531 may be connected to a first potential V1, and the conductive layer 550 is connected to a second potential V2 (e.g. a ground potential) of a supply voltage. The electrode portion 575 may again be part of or be connected to a power line 565 of the integrated circuit.

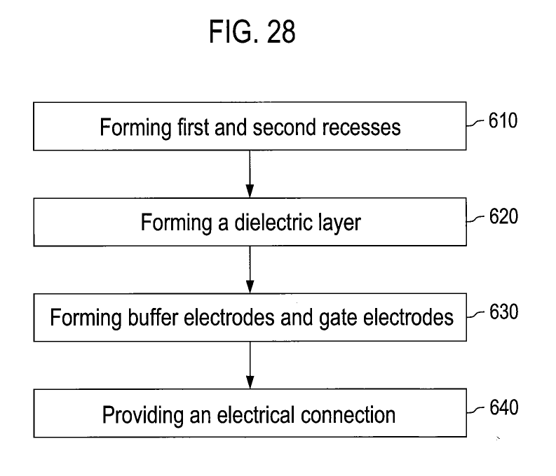

FIG. 28 shows a flow diagram illustrating an example of a method for manufacturing an integrated circuit. The method includes forming first recesses in a buffer capacitor region of a provided substrate and second recesses in an array region of the substrate (step 610), forming a dielectric layer on the surface of the substrate in the first and second recesses (step 620), and forming buffer electrodes for buffer capacitors in the buffer capacitor region and gate electrodes for transistors in the array region (step 630). Here, the buffer electrodes may at least partially fill the first recesses and the gate electrodes at least partially fill the second recesses such that the dielectric layer is disposed between the substrate and the buffer electrodes, and between substrate and the gate electrodes. In a further step 640, an electrical connection may be provided between the buffer electrodes and a power line of the integrated circuit.

The embodiments described in conjunction with the drawings are examples. Moreover, further embodiments may be realized which comprise further modifications. As an example, with respect to the buffer capacitor region 101 depicted in FIG. 12, the conductive layer 145 may be subjected to an additional structuring process, thereby providing—instead of the depicted plane electrode portion 175—a further conductor path on top of the conductor portions 131 in the recesses 111. This also applies to the buffer capacitor regions 181, 301 of FIGS. 13 and 25, and to the buffer capacitors of FIGS. 26 and 27.

With respect to the buffer capacitors of FIGS. 26 and 27, it is alternatively possible to carry out an additional recess etching process after deposition of the conductive layers 445, 545, in order to provide the electrodes 431, 531 only in a lower recess section of the recesses 411, 511. In this case, a further dielectric layer may be fabricated in an upper recess section, and a spacer layer and contact plugs may be produced so that a configuration comparable to that of FIG. 6 is provided.

Regarding the buffer capacitor region 101 of FIG. 6, instead of the conductor path 160, a plane electrode portion may alternatively be provided on the spacer layer 127 and being connected to the contact plugs 150. This also applies to the buffer capacitor region 301 of FIG. 20a.

A further modification includes providing different dielectric layers in a portion of the recesses. As an example, it is possible to provide a first dielectric layer on the bottom and on sidewalls of the recesses in a lower recess section, and to provide a second dielectric layer adjoining to the first dielectric layer on sidewalls of the recesses in an upper recess section (not shown). Here, the thickness of the first dielectric layer may exceed the thickness of the second dielectric layer. Conductor portions or electrodes subsequently produced in the recesses may be enclosed by the first and second dielectric layer.

With respect to a fabrication method, it is possible to carry some of the processes simultaneously to produce electrodes or conductor portions in a buffer capacitor region and to produce conductor portions in a further (array) region of a substrate. Formation of recesses and of a dielectric layer at an edge or sidewall portion of the recesses may for example be performed by means of common process steps, wherein deposition of a conductive layer in the recesses is performed separately. In this case, it is additionally possible to apply different conductive materials for the conductor portions in the buffer capacitor region and in the further (array) substrate region. A further example relates to the buffer capacitors depicted in FIG. 26. Formation of the recesses 411, deposition of the dielectric layer 420 and the conductive layer 445 may also be carried out in a further substrate region (e.g. for producing word or bit lines), wherein deposition of the conductive layer 450 may be restricted to the buffer capacitor region. Alternatively, the complete formation of buffer capacitors in a region of a substrate may be performed independently from other substrate regions, thus providing buffer electrodes being connected to each other on a singulated circuit chip.

In addition, the indicated materials or details regarding applied processes are examples and not limiting. Instead of the given materials, other materials may be employed. Specified processes may be substituted by other processes, as well.

Moreover, formation of buffer capacitors as described above is not limited to a memory device. The methods may be carried out in a similar way in order to provide buffer electrodes being connected to each other on other circuit devices or chips. This includes circuit devices like e.g. a central processing unit (CPU) circuit, a signal processing circuit, or a logic circuit. At this, buffer capacitors may again be fabricated in a substrate region independently from other substrate regions, or (a fraction of) process steps may be carried out simultaneously in the buffer capacitor region and in a further substrate region.

The preceding description describes examples of embodiments of the invention. The features disclosed therein and the claims and the drawings can, therefore, be useful for realizing the invention in its various embodiments, both individually and in any combination. While the foregoing is directed to embodiments of the invention, other and further embodiments of this invention may be devised without departing from the basic scope of the invention, the scope of the present invention being determined by the claims that follow.

What is claimed is:

1. An integrated circuit with an array region and a buffer region on a substrate, comprising:
a buffer capacitor in the buffer region comprising a number of buffer electrodes and a first dielectric layer, the buffer electrodes being at least partially arranged in recesses formed in the substrate, and the first dielectric layer being disposed between the buffer electrodes and the substrate in at least a sidewall portion of the recesses; and
a transistor in the array region comprising a gate electrode and a second dielectric layer, the second dielectric layer being disposed between the gate electrode and the substrate.

2. The integrated circuit of claim 1, wherein the first and second dielectric layer form parts of the same dielectric layer, and wherein the buffer electrodes and the gate electrodes form parts of the same layer.

3. The integrated circuit of claim 1, wherein each recess comprises an upper section and a lower section, the lower section adjoining to a bottom of the recess and including a respective buffer electrode, and the upper section adjoining to a surface of the substrate and including a further dielectric layer above the buffer electrode.

4. The integrated circuit of claim 3, further comprising a dielectric spacer layer on the surface of the substrate and a conductor path arranged above the dielectric spacer layer, wherein the conductor path is connected to the buffer electrodes by contact plugs extending through the dielectric spacer layer and the further dielectric layer.

5. The integrated circuit of claim 4, wherein the conductor path comprises a plane electrode portion.

6. The integrated circuit of claim 1, wherein each buffer electrode completely fills a recess.

7. The integrated circuit of claim 1, wherein a substrate region adjoining to the recesses comprises a doped semiconductor material.

8. The integrated circuit of claim 1, wherein the substrate further comprises a conductive layer adjacent to the first dielectric layer.

9. The integrated circuit of claim 1, wherein the gate electrode is arranged in a further recess in the array region, and wherein the depth of the recesses in the buffer region exceeds the depth of the further recess in the array region.

10. The integrated circuit of claim 1, wherein the gate electrode is arranged in a further recess in the array region, and wherein the thickness of the buffer electrodes exceeds the thickness of the gate electrode.

11. The integrated circuit of claim 1, wherein the thickness of the first dielectric layer is different from the thickness of the second dielectric layer.

12. An integrated circuit on a substrate, comprising:
a buffer capacitor comprising a number of buffer electrodes and a first dielectric layer, the buffer electrodes being at least partially arranged in first recesses formed in the substrate, and the first dielectric layer being disposed between the buffer electrodes and the substrate; and
a transistor comprising a gate electrode and a second dielectric layer, the gate electrode being at least partially arranged in a second recess formed in the substrate, and the second dielectric layer being disposed between the gate electrode and the substrate, wherein the buffer electrodes are connected to a power line of the integrated circuit.

13. The integrated circuit of claim 12, wherein each first recess comprises an upper section and a lower section, the lower section adjoining to a bottom of the recess and including a respective buffer electrode, and the upper section adjoining to a surface of the substrate and including a further dielectric layer above the buffer electrode.

14. The integrated circuit of claim 13, further comprising a dielectric spacer layer on the surface of the substrate and a conductor path arranged above the dielectric spacer layer, wherein the conductor path is connected to the buffer electrodes by contact plugs extending through the dielectric spacer layer and the further dielectric layer.

15. The integrated circuit of claim 12, wherein each buffer electrode completely fills a first recess.

16. An integrated circuit with an array region and a buffer region on a substrate, comprising:
a number of first recesses in the buffer region and a number of second recesses in the array region, the first and second recesses extending from a surface of the substrate;
a conductor portion in each of the first and second recesses; and
a dielectric layer in each of the first and second recesses, the dielectric layer being disposed between the conductor portions and the substrate, wherein each conductor portion in the first recesses forms part of a buffer capacitor, and wherein each conductor portion in the second recesses forms part of a word line.

17. The integrated circuit of claim 16, wherein the depth of the first recesses exceeds the depth of the second recesses.

18. The integrated circuit of claim 16, wherein the thickness of the conductor portions in the first recesses exceeds the thickness of the conductor portions in the second recesses.

19. The integrated circuit of claim 16, wherein the buffer capacitor further comprises a plane electrode portion being connected to the conductor portions in the first recesses.

20. A buffer capacitor configured to stabilize a supply voltage of an integrated circuit on a substrate, comprising:
a plurality of recesses in the substrate extending from a surface of the substrate;
a conductor portion in each of the recesses;
a dielectric layer in each of the recesses, the dielectric layer being disposed between the conductor portions and the substrate; and
a conductor path configured to couple the conductor portions to the supply voltage.

21. The buffer capacitor of claim 20, wherein each recess comprises an upper section and a lower section, the lower section adjoining to a bottom of the recess and including a respective conductor portion, and the upper section adjoining to the surface of the substrate and including a further dielectric layer above the conductor portion.

22. The buffer capacitor of claim 21, further comprising a dielectric spacer layer on the surface of the substrate, wherein the conductor path is connected to the buffer electrodes by contact plugs extending through the dielectric spacer layer and the further dielectric layer.

23. The buffer capacitor of claim 20, wherein the conductor path comprises a plane electrode portion.

24. An integrated circuit on a substrate, comprising:
a number of trenches in the substrate extending from a surface of the substrate;
a conductor portion and a dielectric layer being at least partially arranged in each of the trenches, the dielectric layer being disposed between the conductor portions and the substrate; and
a conductor path which connects the conductor portions to each other, wherein the trenches and the conductor portions run parallel to each other.

25. The integrated circuit of claim 24, wherein each trench comprises an upper section and a lower section, the lower section adjoining to a bottom of the trench and including a respective conductor portion, and the upper section adjoining to the surface of the substrate and including a further dielectric layer above the conductor portion.

26. The integrated circuit of claim 25, further comprising a dielectric spacer layer on the surface of the substrate, wherein the conductor path is connected to the buffer electrodes by contact plugs extending through the dielectric spacer layer and the further dielectric layer.

27. The integrated circuit of claim 24, wherein the conductor path runs in a direction perpendicular to the trenches.

28. The integrated circuit of claim 24, wherein the conductor path comprises a plane electrode portion.

29. The integrated circuit of claim 24, wherein each conductor portion completely fills a trench.

30. A method of manufacturing an integrated circuit on a substrate, comprising:
forming first recesses in a buffer region and second recesses in an array region of the substrate, the first and second recesses extending from a surface of the substrate;
forming a dielectric layer on the surface of the substrate in the first and second recesses;
forming buffer electrodes of a buffer capacitor in the buffer region and gate electrodes of a transistor in the array region of the substrate, the buffer electrodes at least partially filling the first recesses and the gate electrodes at least partially filling the second recesses such that the dielectric layer is disposed between the substrate and the buffer electrodes and between the substrate and the gate electrodes; and
providing an electrical connection between the buffer electrodes and a power line of the integrated circuit.

31. The method of claim 30, wherein forming the buffer electrodes comprises:
filling the first recesses with a conductive layer; and
removing a portion of the conductive layer so that the conductive layer remains in a lower section of the first recesses.

32. The method of claim 31, further comprising:
filling an upper section of the first recesses with a further dielectric layer which covers the buffer electrodes; and
forming a dielectric spacer layer on the surface of the substrate, wherein providing the electrical connection comprises forming contact plugs being connected to the buffer electrodes and extending through the dielectric spacer layer and the further dielectric layer in the upper section of the first recesses.

33. The method of claim 32, further comprising:
forming a further conductor path on the spacer layer being connected to the contact plugs.

34. The method of claim 30, wherein the dielectric layer is further formed on the surface of the substrate outside the recesses, and wherein forming the buffer electrodes comprises forming a conductive layer on the dielectric layer, the conductive layer completely filling the first recesses.

35. The method of claim 30, further comprising performing an ion implantation process so that a substrate region adjoining to the first recesses comprises a doped semiconductor material.
